(19) United States
(12) Patent Application Publication
(10) Pub. No.: US 2025/0215269 A1
(43) Pub. Date: Jul. 3, 2025

(54) ADHESIVE FILM FOR WAFER BACK GRINDING

(71) Applicant: INNOX Advanced Materials Co., Ltd., Asan-si (KR)

(72) Inventors: Kyung-Woo Park, Asan-si (KR); Kun-Young Ko, Asan-si (KR); Chul Jeong, Asan-si (KR); Yeon-Jun Kee, Asan-si (KR)

(21) Appl. No.: 19/004,446

(22) Filed: Dec. 29, 2024

(30) Foreign Application Priority Data
Dec. 29, 2023 (KR) 10-2023-0197897
Dec. 24, 2024 (KR) 10-2024-0195004

(51) Int. Cl. C09J 7/29; B24B 7/22; H01L 21/304

(52) U.S. Cl. CPC C09J 7/29; B24B 7/228; H01L 21/304; C09J 2203/326; C09J 2433/006

(57) ABSTRACT

Embodiments of the present invention provide adhesive films that can be used to protect a surface of a semiconductor wafer during a wafer back grinding step, also known as wafer lapping, wafer thinning, backlap, or backfinish, as part of a process to form an electronic device, and methods of use thereof. More specifically, the present disclosure relates to an adhesive film for wafer back grinding that maximizes permeation (embeddability) of an adhesive layer of the adhesive film among device components/surface features that can form at least one bump on the device forming surface of the wafer, has an excellent wafer surface protection effect (buffering effect) during the back grinding step and reduces or eliminates the problem of adhesive residue that can be left on the wafer surface after the step of peeling the adhesive film from the wafer surface following the wafer back grinding. The subject adhesive films exhibit excellent processability.

### CROSS REFERENCE TO RELATED APPLICATIONS

This application claims priority from and the benefit of Korean Patent Application No. 10-2023-0197897, filed on Dec. 29, 2023, and Korean Patent Application No. 10-2024-0195004, filed on Dec. 24, 2024, which are hereby incorporated by reference for all purposes as if fully set forth herein.

### FIELD OF THE INVENTION

The field of the invention generally relates to semiconductor device processing. In particular, the present disclosure relates to methods of improving protection for device components and features during the subprocess of wafer back grinding.

### BACKGROUND

With recent developments in microelectronics technologies, miniaturization, high density, and thinning of semiconductor chips are frequently required, and thus thinning of wafers is also required. A representative method for thinning a wafer chip is to reduce a thickness by grinding a back of the wafer, and the thinning of the wafer can be achieved by performing a grinding process that varies according to the type or specification of an electronic device in which the semiconductor chip is used.

Since the back grinding of a wafer of a semiconductor chip is a process of applying a physical impact, the back grinding of the wafer is performed after attaching an adhesive film for wafer back grinding to protect a front surface of the wafer upon which delicate components of an electronic device have been formed.

On a circuit formation surface of a semiconductor wafer, unevenness having relatively large steps such as bumps as well as circuits may be formed. Due to such a bump structure, when the adhesive film for wafer back grinding is attached and a void is formed between the adhesive film for wafer back grinding and the uneven surface of circuit formation of the semiconductor wafer, stress distribution is generated on the surface of the semiconductor wafer when a circuit non-forming surface (back side) of the semiconductor wafer is ground, resulting in a problem that the semiconductor wafer is easily damaged. In addition, when support strength between an adhesive layer and a buffer layer is weak, the buffer layer is not fixed during the wafer back grinding, and this can cause cracks in the wafer, damage to the chip, or the like.

In addition, to remove the adhesive film for wafer back grinding from the surface of the wafer after wafer back grinding, energy, often ultraviolet light is radiated to reduce adhesion so that the adhesive film can be peeled away, and, in this case, there may be a shaded region in which the radiated energy/light rays do not reach sufficiently the voids formed by the bump structure. This creates a problem because in such a shaded region, it is not easy to peel the adhesive film due to this insufficient curing by the energy/light rays. In addition, when the support strength between the adhesive layer and the buffer layer is weak, the adhesive film for wafer back grinding is not easily peeled from the wafer. In this case, as a result, since a residue of the adhesive derived from the adhesive film is easily left on the surface of the wafer, processability can be impaired, and, consequently, the quality of the semiconductor chip to be manufactured can be adversely affected.

The above information disclosed in this Background section is only for understanding of the background of the inventive concepts, and, therefore, it may contain information that does not constitute prior art.

### SUMMARY

There is, therefore, a need in the art for a better way to protect a circuit forming surface of a semiconductor wafer during the wafer back grinding step of a process of forming an electronic device. The present disclosure is directed to providing an adhesive film for wafer back grinding, wherein the adhesive film is capable of maximizing bump fillability (adhesive permeation into voids among features of a circuit forming surface of the wafer) and, at the same time, increasing support strength between the adhesive layer and the buffer layer, thereby preventing damage to a wafer or a chip during back grinding of a wafer having a bump structure and minimizing a residue when removing an adhesive film after a wafer back grinding process.

Objects of the present disclosure are not limited to the above-described object, and other objects and advantages of the present disclosure which are not mentioned can be understood in light of the following description and more clearly understood in light of example embodiments of the present disclosure. In addition, the objects and advantages of the present disclosure may be achieved by devices and combinations thereof and methods that are described in the claims.

To achieve the above object, according to an aspect of the present disclosure, there may be provided an adhesive film for wafer back grinding, the adhesive film comprising a substrate layer, a buffer layer disposed on the substrate layer, an intermediate support layer disposed on the buffer layer, and an adhesive layer disposed on the intermediate support layer, wherein a thickness of the intermediate support layer exceeds 5% based on a total thickness of the buffer layer, the intermediate support layer, and the adhesive layer, wherein at 25° C., a storage modulus of the adhesive layer is less than a storage modulus of the intermediate support layer, and wherein at 25° C., a storage modulus of the buffer layer is less than a storage modulus of the intermediate support layer.

In some embodiments, the intermediate support layer can be a thermosetting product of a composition including a thermoplastic acryl-based resin.

In some embodiments, a storage modulus of the intermediate support layer at 25° C. can range from about 0.03 MPa to about 0.3 MPa.

In some embodiments, a storage modulus of the adhesive layer at 25° C. can range from about 0.02 MPa to about 0.2 MPa.

In some embodiments, a storage modulus of the buffer layer at 25° C. can range from about 0.02 MPa to about 0.2 MPa.

In some embodiments, in the adhesive film for wafer back grinding, at 25° C., a ratio of a storage modulus of the adhesive layer to a storage modulus of the intermediate support layer can range from about 1:1.1 to about 1:1.4, and, at 25° C., a ratio of a storage modulus of the buffer layer to a storage modulus of the intermediate support layer can range from about 1:1.1 to about 1:1.4.

In some embodiments, in the adhesive film for wafer back grinding, at 60° C., a ratio of a storage modulus of the adhesive layer to a storage modulus of the intermediate support layer can range from about 1:1.1 to about 1:1.3, and, at 60° C., a ratio of a storage modulus of the buffer layer to a storage modulus of the intermediate support layer can range from about 1:1.1 to about 1:1.3.

In some embodiments, the total thickness of the buffer layer, the intermediate support layer, and the adhesive layer can range from about 20 μm to about 600 μm.

In some embodiments, a thickness of the intermediate support layer can range from about 1 μm to about 40 μm.

In certain embodiments, the adhesive film for wafer back grinding can be applied to protect a front side of a semiconductor wafer upon which circuitry of an electronic device has been formed while a back side grinding process of a wafer on which a bump is formed is carried out.

In another aspect, the present invention can comprise a method for protecting electronic device components formed on a front side of a semiconductor wafer during back side grinding of the wafer, the method comprising applying an adhesive film to the front side of the wafer, grinding a back side of the wafer, and removing the film from the front side of the wafer, wherein the adhesive film comprises a substrate layer, a buffer layer disposed on the substrate layer, an intermediate support layer disposed on the buffer layer, and an adhesive layer disposed on the intermediate support layer, wherein a thickness of the intermediate support layer exceeds 5% based on a total thickness of the buffer layer, the intermediate support layer, and the adhesive layer, wherein at 25° C., a storage modulus of the adhesive layer is less than a storage modulus of the intermediate support layer, and wherein at 25° C., a storage modulus of the buffer layer is less than a storage modulus of the intermediate support layer.

In some embodiments, the front side of the wafer can comprise a bump.

In some embodiments, the applying step of the method for protecting electronic device components can leave no gas pockets between the intermediate support layer and the front side of the wafer.

In some embodiments, the removing step of the method for protecting electronic device components can leave no substantial amount of adhesive or adhesive byproduct behind on the front side of the wafer.

It is to be understood that both the foregoing general description and the following detailed description are illustrative and explanatory and are intended to provide further explanation of the invention as claimed.

Other objects, features and advantages of the present invention will become apparent from the following detailed description. It should be understood, however, that the detailed description and the specific examples, while indicating specific embodiments of the invention, are given by way of illustration only, since various changes and modifications within the spirit and scope of the invention will become apparent to those skilled in the art from this detailed description.

### BRIEF DESCRIPTION OF THE DRAWINGS

The accompanying drawings, which are included to provide a further understanding of the invention and are incorporated in and constitute a part of this specification, illustrate embodiments of the invention, and together with the description, serve to explain the inventive concepts.

FIG. 1 illustrates a cross-sectional view of an adhesive film for wafer back grinding according to one embodiment of the present disclosure.

FIG. 2 illustrates a cross-sectional view of a condition in which the adhesive film for wafer back grinding according to one embodiment of the present disclosure is attached to a wafer on which a bump structure is formed.

FIG. 3 illustrates one example of a cross section of the bump structure formed on a surface of the wafer.

FIG. 4 schematically illustrates a flowchart of a process of applying the adhesive film for wafer back grinding according to one embodiment of the present disclosure to a wafer back grinding process and subsequently peeling the adhesive film.

### DETAILED DESCRIPTION

The present invention provides adhesive films that can be used to protect a surface of a semiconductor wafer during a wafer back grinding step, also known as wafer lapping, wafer thinning, backlap, backfinish, or back side grinding, as part of a process to form an electronic device and methods of use thereof. The inventive adhesive films for wafer back grinding maximize permeation (embeddability) of an adhesive layer of the adhesive film among device components that can form at least one bump on the surface of the wafer, thus accommodating flexible electronic devices, and has an excellent wafer surface protection effect (buffering effect) during the back grinding step. The inventive films can also reduce or eliminate the problem of adhesive residue that can be left on the wafer surface after the step of peeling the adhesive film from the wafer surface following the wafer back grinding. The subject adhesive films exhibit excellent processability.

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising.” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

The above-described objects, features, and advantages will be described below in detail with reference to the accompanying drawings, and thus those skilled in the art to which the present disclosure pertains will be able to easily carry out the technical spirit of the present disclosure. In describing the present disclosure, when it is determined that a detailed description of the known technology related to the present disclosure may unnecessarily obscure the gist of the present disclosure, a detailed description thereof will be omitted. Hereinafter, exemplary embodiments according to the present disclosure will be described in detail with reference to the accompanying drawings. In the drawings, the same reference numerals are used to denote the same or similar components.

Since contents not described herein may be technically inferred by those skilled in the art, description thereof will be omitted.

In the present specification, the arrangement of an arbitrary component on an “upper portion (or lower portion)” of a component or “above (or under)” the component may not only mean that the arbitrary component is disposed in contact with an upper surface (or a lower surface) of the component, but also mean that other components may be interposed between the component and the arbitrary component disposed above (or under) the component.

The singular expression used herein includes the plural expression unless the context clearly dictates otherwise. In the present application, terms such as “composed of” or “comprising” should not be construed as necessarily including all of various components described in the specification and should be construed as not including some of the components or further including additional components.

In the present specification, terms such as “one surface,” “the other surface,” etc. are used to distinguish one component from another, and the components are not limited by the above-described terms.

In the present specification, “excellent embeddability for a bump structure, bending, and the like” can mean i) excellent adhesion along bending that is present due to bump structures and the like formed on the semiconductor wafer when attaching the adhesive film to the semiconductor wafer without lifting or forming voids and ii) excellent adhesion along bending that is present due to bump structures and the like when laminating each layer of the adhesive film of the present disclosure.

In the present specification, “room temperature” may be construed as being a temperature of about 23 to 25° C. unless a special temperature value is limited.

In the description of the present specification, “(meth)acrylate” is used as the term including “acrylate” and “methacrylate,” and similar terms are to be construed similarly.

Hereinafter, in the description of the present disclosure, detailed description of related known technologies that can unnecessarily obscure the gist of the present disclosure will be omitted.

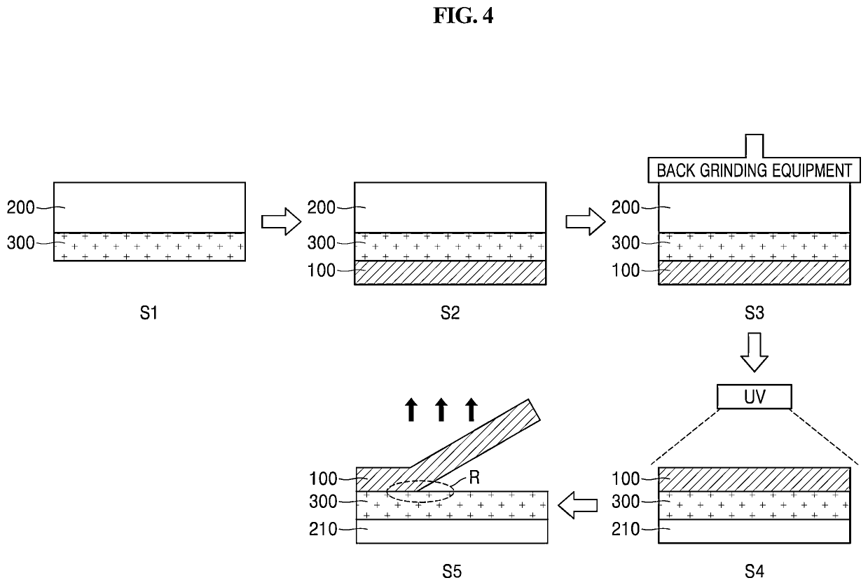

FIG. 3 is an actual enlarged photo image of a structure of a bump 300 formed on a surface of a wafer 200, and due to a rounded shape of the bump 300, a void (exemplarily marked by a dotted circle) is formed between the wafer 200 and the bump 300. FIG. 3 illustrates a structure of one bump, and as a large number of bumps are formed on the wafer, a region of the void also increases. Accordingly, as the stress applied during wafer back grinding is unevenly distributed to the wafer due to voids unfilled by the adhesive of an adhesive film, the wafer can be damaged. In addition, these voids act as shaded regions to which energy/UV light radiated to remove an adhesive film for wafer processing cannot reach. Accordingly, there is a need for an adhesive film for wafer back grinding, which can maximize bump fillability.

FIG. 4 exemplarily illustrates a flowchart of a process of applying an adhesive film 100 for wafer back grinding according to one embodiment of the present disclosure to a wafer and radiating energy/light after back grinding to reduce adhesion and allow the adhesive film to be peeled.

Specifically, S1 of FIG. 4 shows an operation of preparing a wafer (loading the wafer) before a wafer back grinding process and illustrates a bump 300 formed on a surface of a wafer 200. The bump 300 is illustrated as a layer structure with a surface for schematic illustration and does not actually have a layer structure.

S2 of FIG. 4 is an operation of attaching (or attaching) the adhesive film 100 for wafer back grinding of the present disclosure to the surface of the wafer, and thus the adhesive film 100 serves to protect the surface of the wafer 200 during back grinding.

S3 of FIG. 4 schematically illustrates performing a back grinding process, and the back grinding process may be used without limitation with various back grinding equipment used in the art, and, for example, equipment that may load a wafer on a chuck table, and then a rotating grinding wheel or the like may be used.

S4 of FIG. 4 shows an operation of radiating energy rays (e.g., ultraviolet rays) to allow peeling of the adhesive film 100 after the back grinding process and schematically illustrates that the thickness of the wafer 210 after the back grinding process is reduced in comparison to the wafer 200 before the back grinding process.

S5 of FIG. 4 schematically illustrates an operation of peeling the adhesive film 100 after the back grinding process. In this case, when the exposure to the energy/UV light reaching the adhesive film 100 is insufficient, adhesive strength is not sufficiently reduced to a degree at which the adhesive film can be peeled well. In addition, when support strength between the adhesive layer and a layer thereabove is low, a residue of the adhesive film 100 for wafer back grinding may be left in the peeling operation. As described above, a region R in which the residue of an adhesive is left is exemplarily illustrated in FIG. 4.

When the residue of the adhesive film 100 for wafer back grinding is left on the wafer, a problem that adversely affects processability and the quality of the semiconductor chip to be manufactured may occur.

When the degree of voids and bending due to bumps formed on the wafer 200 is severe and fillability is insufficient, a shaded region which energy/UV light rays cannot reach also increases, thereby causing the problem described above-peeling of the adhesive film from the shaded area can be difficult and adhesive residue can be left on the wafer surface, adversely affecting processing quality. In addition, this problem is even worse when the adhesive layer is not supported by the layer thereabove.

As a result of close study based on such a problem, the present inventors unexpectedly found an advantageous configuration for an adhesive film for wafer back grinding involving certain relationships between both a thickness and a storage modulus of an intermediate support layer as compared with those parameters in other layers of a laminated adhesive film for wafer back grinding, the adhesive film including sequentially a substrate layer, a buffer layer, the intermediate support layer, and an adhesive layer. That is, the inventor completed the invention related to the adhesive film for wafer back grinding, which sequentially includes the substrate layer, the buffer layer, the intermediate support layer, and the adhesive layer, adjusts the thickness of the intermediate support layer in the relationship with other layers and adjusts the storage modulus, thereby maximizing bump fillability (embeddability) to prevent voids from being formed and allowing energy/UV light rays to reach all regions of adhesive and allow the adhesive film to be removed evenly and sufficiently, and includes the intermediate support layer to increase support strength between the buffer layer, the intermediate layer, and the adhesive layer, thereby preventing the residue of the adhesive layer from being left when peeling.

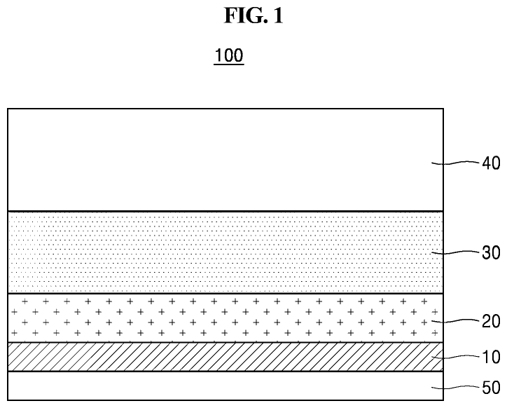

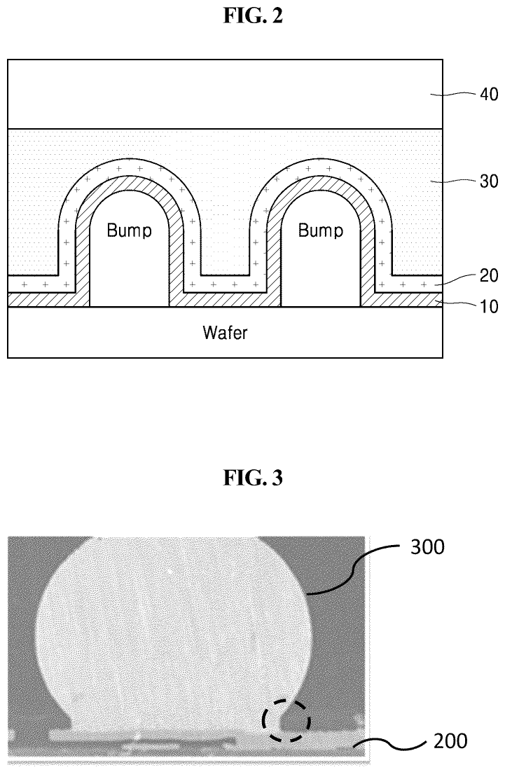

As one embodiment of the present disclosure, as illustrated in FIG. 1, since the adhesive film 100 for wafer back grinding of the present disclosure has a structure including a substrate layer 40, a buffer layer 30 disposed on the substrate layer, an intermediate support layer 20 disposed on the buffer layer, and an adhesive layer 10 disposed on the intermediate support layer, the adhesive film 100 for wafer back grinding and each structural layer thereof will be described in detail. A release film 50 can be disposed on the adhesive layer to facilitate shipping and handling of the adhesive film for wafer back grinding product.

### The Substrate Layer

The substrate layer of the adhesive film for wafer back grinding of the present disclosure may be formed of a material having a high tensile modulus. For example, the substrate layer may have a tensile modulus of 1,000 MPa or more, 1,200 MPa or more, 1,500 MPa or more, 2,000 MPa or more, or 3,000 MPa or more, with the tensile modulus based on a measured value at 23° C. When the tensile modulus of the substrate layer is relatively low, that is, less than 1,000 MPa, support strength for the wafer or the semiconductor chip is low, and thus there is a possibility that the semiconductor chip may delaminate from the substrate during the back grinding process.

The substrate layer may include a substrate layer formed of one or more selected from the group consisting of polyethylene terephthalate (PET), polyethylene naphthalate (PEN), polybutylene terephthalate (PBT), a polyester such as a totally aromatic polyester, polyimide (PI), polyamide (PA), polycarbonate (PC), polyacetal, a modified polyphenylene oxide, polyphenylene sulfide, polysulfone, polyether ketone, and biaxially oriented polypropylene. Preferably, the substrate layer may include a substrate layer formed of PET.

A thickness of the substrate layer is not particularly limited, but for example, each substrate layer may have a thickness of about 10 μm to about 150 μm.

Meanwhile, the substrate layer may include small amounts of any or all of various additives such as a coupling agent, a plasticizer, an antistatic agent, an antioxidant, or the like as needed.

### The Buffer Layer

The buffer layer of the present disclosure may be disposed on the substrate layer and may affect bump fillability and serve to absorb vibrations and impacts generated during wafer back grinding. In addition, the buffer layer can exhibit excellent support strength in the presence of the intermediate support layer, thereby preventing cracks in the wafer or damage to the chip from occurring because the buffer layer is not fixed during grinding.

From this point of view, a storage modulus of the buffer layer at 25° C. may range from about 0.02 MPa to about 0.2 MPa. In addition, the storage modulus of the buffer layer at 60° C. may range from about 0.01 MPa to about 0.1 MPa. Accordingly, it is possible to increase bump fillability, sufficiently absorb impacts and vibrations during grinding, and maintain adhesive strength with the intermediate support layer present, while preventing adhesive residue from being left behind after the adhesive film is peeled away following back grinding. For example, when the storage modulus of the buffer layer is less than the above range at each temperature, there may be a problem that the adhesive gets on a blade when a tape is attached to the wafer and the wafer is then cut in a subsequent dicing process, fluidity may increase due to heat generated during grinding to cause damage to the wafer and/or the chip, and adhesive residue may be left after the tape is removed. On the other hand, if the storage modulus of the buffer layer exceeds the above range at each temperature, bump fillability decreases to make the void larger, and the impacts and vibrations cannot be smoothly absorbed during grinding, thereby causing damage to the bump and the wafer. For example, the storage modulus of the buffer layer at 25° C. may be 0.02 MPa or more or 0.05 MPa or more or may be 0.2 MPa or less or 0.1 MPa or less. In addition, the storage modulus of the buffer layer at 60° C. may be 0.01 MPa or more or 0.05 MPa or more or may be 0.1 MPa or less or 0.07 MPa or less. The buffer layer is not particularly limited as long as it may exhibit the above characteristics, and for example, the characteristics of the buffer layer may be controlled by a composition for forming a buffer layer, a manufacturing method, or the like.

The buffer layer may include a photocurable material of the composition for forming a buffer layer. Heat is generated during the back grinding process, and when a thermosetting material is included in the buffer layer, a sticky residue is caused to form by an increase in fluidity at high temperatures, and thus a residue is left or the thickness of the film is changed, thereby causing a thickness deviation of a final chip. On the other hand, the buffer layer may be cured without any difference in curing degree on a surface, forming a predetermined thickness by using a photocurable material, preventing the above problems, including the occurrence of the residue and the thickness deviation.

The buffer layer may be formed by photo-curing a composition including a first (meth)acrylate-based adhesive resin within a range to provide a storage modulus within the above designated range.

The first (meth)acrylate-based adhesive resin, which is generally used in the art, may be selected without limitation within a range capable of achieving the object of the present disclosure. For example, the first (meth)acrylate-based adhesive resin may be a polymer of a (meth)acryl-based monomer having an alkyl group having 1 to 14 carbon atoms, and specifically, may be one or more polymers selected from the group consisting of ethylhexyl (meth)acrylate, butyl (meth)acrylate, ethyl (meth)acrylate, methyl (meth)acrylate, acrylic acid, hydroxyethyl (meth)acrylate, isobornyl (meth)acrylate, and hydroxybutyl (meth)acrylate, and preferably, may be a polymer obtained by polymerizing a monomer including ethylhexyl (meth)acrylate, isobornyl (meth)acrylate, and methyl (meth)acrylate.

In addition, the composition for the buffer layer may further include a photoinitiator and a curing agent. The photoinitiator and the photo-curing agent are not particularly limited as long as they are commonly used in the art. For example, the photoinitiator may include hydroxycyclohexylphenylketone (Irgacure 184), 2-methyl-1 [4-(methylthio)phenyl]-2-mopolyno-propane-1-on (Irgacure 907), a-methoxy-a-hydroxyacetophenone (Irgacure 651), 2-hydroxy-2-methyl-1-phenyl-1-on (Irgacure 1173), and the like. In addition, the curing agent may further include 1,6-hexanediol diacrylate (HDDA). In addition, the composition for the buffer layer may further include a crosslinking agent, and the type of the composition is not particularly limited as long as it is commonly used in the art. For example, an isocyanate-based crosslinking agent may be used.

The thickness of the buffer layer is not particularly limited, and may have, for example, a thickness of about 10 μm to about 500 μm, for example, a thickness of about 50 μm to about 500 μm, for example, a thickness of about 70 μm to about 500 μm.

### The Adhesive Layer

The adhesive layer of the present disclosure is a part adhered (or attached) to a wafer and is required to exhibit high bump fillability to prevent a void between the adhesive film for wafer back grinding and the unevenness on the circuit formation surface of the semiconductor wafer, thereby preventing a shaded region from being formed during the ultraviolet irradiation step that facilitates peeling of the adhesive film following back grinding. In addition, the adhesive layer can exhibit excellent support strength in the presence of the intermediate support layer, thereby preventing the residue of the adhesive layer from being left when peeling the adhesive film.

From this point of view, the storage modulus of the adhesive layer at 25° C. may range from about 0.02 MPa to about 0.2 MPa. In addition, the storage modulus of the adhesive layer at 60° C. may range from about 0.01 MPa to about 0.1 MPa. When the storage modulus at each temperature of the adhesive layer is less than the above range, a degree of agglomeration may be too low, causing an adhesive residue to be left during peeling, the adhesive may get on the blade when the tape is attached to the wafer and then the wafer is cut in a subsequent dicing process, and fluidity may increase due to heat generated during grinding, thereby causing damage to the wafer and/or the chip. On the other hand, when the storage modulus at each temperature of the adhesive layer exceeds the above range, adhesion may be insufficient when the adhesive film is laminated on the wafer. In addition, due to a reduction in bump fillability, voids are formed between the adhesive film for wafer back grinding and the uneven circuit formation surface of the semiconductor wafer, thereby causing uneven stress distribution during grinding and damage to the wafer. In addition, since the energy/UV light rays do not sufficiently reach the adhesive film, difficulty with peeling the adhesive film for wafer back grinding may occur and residue of the adhesive layer can be left on the wafer surface. For example, the storage modulus of the adhesive layer at 25° C. may be about 0.02 MPa or more or about 0.05 MPa or more or may be about 0.2 MPa or less or about 0.15 MPa or less. In addition, the storage modulus of the adhesive layer at 60° C. may be about 0.01 MPa or more or about 0.05 MPa or more or may be about 0.1 MPa or less or about 0.09 MPa or less.

The storage modulus of the adhesive layer may be adjusted by adjusting a composition for forming the adhesive layer.

The adhesive layer may be formed of various adhesive compositions, such as an acryl-based adhesive composition, a silicon-based adhesive composition, a polyester-based adhesive composition, a urethane-based adhesive composition, and a styrene-diene block copolymer adhesive composition, which are known UV polymerizable adhesive compositions, within a range showing a storage modulus within the above range, but may be preferably formed of an acryl-based adhesive composition.

The adhesive layer may be formed by thermally curing a composition for an adhesive layer, which includes a second (meth)acrylate-based adhesive resin. The adhesive layer may be subjected to an additional polymerization reaction during UV radiation before peeling the film after grinding.

For example, the second (meth)acrylate-based adhesive resin, which is generally used in the art, may be selected without limitation within a range capable of achieving the object of the present disclosure. For example, the second (meth)acrylate-based adhesive resin may be a polymer of a (meth)acryl-based monomer having an alkyl group having 1 to 14 carbon atoms, and specifically, may be one or more polymers selected from the group consisting of ethylhexyl (meth)acrylate, butyl (meth)acrylate, ethyl (meth)acrylate, methyl (meth)acrylate, acrylic acid, hydroxyethyl (meth)acrylate, isobornyl (meth)acrylate, and hydroxybutyl (meth)acrylate. For example, the second (meth)acrylate-based adhesive resin may be a polymer obtained by polymerizing a monomer including ethylhexyl (meth)acrylate, butyl (meth)acrylate, methyl (meth)acrylate, and hydroxyethyl (meth)acrylate, but is not limited thereto.

The composition for forming the adhesive layer may include a monomer with an unreacted vinyl group. Due to an initiation reaction when UV is radiated, a photoreactive initiator included in the adhesive layer may be bonded with the unreacted vinyl group of the monomers to reduce the adhesive strength of the adhesive layer, thereby preventing the residue of the adhesive film for wafer back grinding from being left in the peeling operation. In addition, the monomer with the unreacted vinyl group may react with the monomer with an available unreacted vinyl group of the intermediate support layer, thereby further increasing bonding strength between the adhesive layer and the intermediate support layer to further increase the support strength of the adhesive film for wafer back grinding. Accordingly, it is possible to more easily prevent the residue of the adhesive film for wafer back grinding from being left behind in the peeling operation.

The monomer with the unreacted vinyl group may be one selected from the group consisting of 2-methacryloyloxyethyl isocyanate, 2-acryloyloxyethyl isocyanate, m-isopropenyl-a, a-dimethylbenzyl isocyanate, glycidyl methacrylate, a 2-hydroxyethylvinyl ether, a 4-hydroxybutylvinyl ether, a diethylene glycol monovinyl ether, and a combination thereof. The monomer with the unreacted vinyl group may be used within a range capable of achieving the object of the present disclosure. For example, the monomer with the unreacted vinyl group may be included in an amount of 3 to 20 parts by weight based on 100 parts by weight of the second (meth)acrylate-based adhesive resin. When the content of the monomer with the unreacted vinyl group is less than the above range, there may be a problem that adhesive strength is not sufficiently reduced after UV radiation, and when the content exceeds the above range, there may be a problem that a residue may occur due to a crack phenomenon of the adhesive layer when the film is peeled due to over-curing.

In addition, the composition for forming the adhesive layer may further include a photopolymerization initiator and a crosslinking agent. The choice of these components is not particularly limited as long as they are commonly used in the art.

The photopolymerization initiator is a material that initiates a UV curing reaction by UV radiation, and the type and content thereof are appropriately selected and used considering a curing rate of a resin composition or the like, and, for example, the photopolymerization initiator may include hydroxycyclohexylphenyl ketone (Irgacure 184), 2-methyl-1 [4-(methylthio)phenyl]-2-mopolyno-propane-1-on (Irgacure 907), a-methoxy-a-hydroxyacetophenone (Irgacure 651), 2-hydroxy-2-methyl-1-phenyl-propane-1-on (Irgacure 1173), and the like.

In addition, the composition for the adhesive layer may further include a crosslinking agent, and the type of the composition is not particularly limited as long as it is commonly used in the art, and, for example, an isocyanate-based crosslinking agent may be used.

The thickness of the adhesive layer 30 is not particularly limited and may be, for example, a thickness of about 5 μm to about 30 μm or about 10 μm to about 30 μm.

### Intermediate Support Layer

The intermediate support layer of the present disclosure may be positioned between the buffer layer formed on the substrate layer and the adhesive layer attached to the wafer and may serve to support the buffer layer and the adhesive layer. In addition, by having the buffer layer fixed well during grinding, it is possible to prevent cracks in the wafer or damage to the chip due to impacts and vibrations generated during grinding. In addition, with excellent support strength with the adhesive layer, it is possible to prevent adhesive residue from being left by the adhesive layer anchored on the wafer during peeling of the adhesive film from the wafer.

From this point of view, a storage modulus of the intermediate support layer at 25° C. may range from about 0.03 MPa to about 0.3 MPa. In addition, the storage modulus of the intermediate support layer at 60° C. may range from about 0.02 MPa to about 0.2 MPa. For example, when the storage modulus at each temperature of the intermediate support layer is less than the above range, the support strength between the buffer layer and the adhesive layer is insufficient, and thus the buffer layer is not fixed well during grinding, resulting in problems of causing cracks in the wafer or damage to the chip due to impacts and vibrations during grinding and leaving behind adhesive residue of the adhesive layer during peeling. On the other hand, when the storage modulus at each temperature of the intermediate support layer exceeds the above range, the support strength between the buffer layer and the adhesive layer may increase, but the semiconductor chip can collide in the back grinding process (back grinding process), and bump fillability can be lowered. In addition, impacts and vibrations cannot be smoothly absorbed during grinding, thereby causing damage to the bumps and the wafer. For example, the storage modulus of the intermediate support layer at 25° C. may be about 0.03 MPa or more, about 0.05 MPa or more, or about 0.1 MPa or more or may be about 0.3 MPa or less or about 0.2 MPa or less. In addition, the storage modulus of the intermediate support layer at 60° C. may be about 0.02 MPa or more or about 0.1 MPa or more or may be about 0.2 MPa or less or about 0.15 MPa or less. The intermediate support layer is not particularly limited as long as it can exhibit the above characteristics, and for example, the characteristics of the intermediate support layer may be controlled by a composition for forming an intermediate support layer, a manufacturing method, or the like.

The intermediate support layer may be a thermosetting product of a composition including a thermoplastic acryl-based resin. The intermediate support layer may include a third (meth)acrylate-based adhesive resin within a range showing a storage modulus within the above range. The third (meth)acrylate-based adhesive resin, which is generally used in the art, may be selected without limitation within a range capable of achieving the object of the present disclosure. For example, the third (meth)acrylate-based adhesive resin may be a polymer of a (meth)acryl-based monomer having an alkyl group having 1 to 14 carbon atoms, and specifically, may be one or more polymers selected from the group consisting of ethylhexyl (meth)acrylate, butyl (meth)acrylate, ethyl (meth)acrylate, methyl (meth)acrylate, acrylic acid, hydroxyethyl (meth)acrylate, isobonyl (meth)acrylate, and hydroxybutyl (meth)acrylate. For example, the third (meth)acrylate-based adhesive resin may be a polymer obtained by polymerizing a monomer including n-butyl (meth)acrylate, 2-ethylhexyl (meth)acrylate, methyl (meth)acrylate, 2-hydroxyethyl (meth)acrylate, and acrylic acid, but is not limited thereto.

In addition, the composition for forming the intermediate support layer may further include a crosslinking agent and is not particularly limited as long as it is commonly used in the art. For example, an isocyanate-based crosslinking agent may be used. A thickness of the intermediate support layer exceeds 5% based on a total thickness of the buffer layer, the intermediate support layer, and the adhesive layer. For example, the above thickness may be more than about 5% and about 30% or less. Accordingly, it is possible to prevent the residue of the adhesive derived from the adhesive film from being left behind when peeling the adhesive film from the wafer, without reducing bump fillability. For example, the thickness of the intermediate support layer may be more than about 5% or about 7% or more based on the total thickness of the buffer layer, the intermediate support layer, and the adhesive layer and may be about 30% or less, about 25% or less, or about 20% or less.

The total thickness of the buffer layer, the intermediate support layer, and the adhesive layer may range from about 20 μm to about 600 μm. For example, the total thickness may range from about 50 μm to about 200 μm. In addition, the thickness of the intermediate support layer is not particularly limited and, for example, may range from about 1 μm to about 40 μm.

### Adhesive Film 100 for Wafer Back Grinding

The adhesive film 100 for wafer back grinding of the present disclosure may include the intermediate support layer 20 between the buffer layer 30 formed on the substrate layer 40 and the adhesive layer 10 attached to the wafer, thereby increasing the support strength between the buffer layer and the adhesive layer. At the same time, when the adhesive film for wafer back grinding is applied to the back grinding process of the wafer on which bumps are formed, it is possible to maximize bump fillability (embeddability), thereby solving problems caused by voids in the adhesive layer and bending due to bumps and the shaded region caused by the voids when irradiating with energy/UV light rays.

From such a perspective, the adhesive film for wafer back grinding satisfies Expressions 1 and 2 below.

### [Expression 1]

At 25° C., the storage modulus of the adhesive layer is less than the storage modulus of the intermediate support layer.

### [Expression 2]

At 25° C., the storage modulus of the buffer layer is less than the storage modulus of the intermediate support layer

Here, the storage moduli of Expressions 1 and 2 are storage moduli when the adhesive film for wafer back grinding is attached to the wafer.

The intermediate support layer can exhibit the desired support strength by having a high storage modulus in comparison with both the buffer layer and the adhesive layer. In addition, the buffer layer positioned on the substrate layer and the adhesive layer attached to the wafer can exhibit a low storage modulus in comparison with that of the intermediate support layer, thereby maximizing bump fillability.

Specifically, the adhesive film for wafer back grinding can satisfy Expressions 3 and 4 below.

### [Expression 3]

At 25° C., a ratio of the storage modulus of the adhesive layer to the storage modulus of the intermediate support layer is 1:1.1 to 1:1.4.

### [Expression 4]

At 25° C., a ratio of the storage modulus of the buffer layer to the storage modulus of the intermediate support layer is 1:1.1 to 1:1.4.

In the relationship between the adhesive layer and the buffer layer, when the storage modulus of the intermediate support layer is less than the above range, a residue of the adhesive layer may be left behind when the adhesive film for wafer back grinding is peeled from the wafer, and impacts and vibrations cannot then be smoothly absorbed during grinding, thereby causing damage to the bump and the wafer. On the other hand, when the storage modulus of the intermediate support layer exceeds the above range, bump fillability can be reduced, and a void may be formed between the adhesive film for wafer back grinding and the uneven circuit formation surface of the semiconductor wafer, thereby causing the problems that stress is unevenly distributed during grinding and the wafer is easily damaged.

In addition, the adhesive film for wafer back grinding can satisfy Expressions 5 and 6 below.

### [Expression 5]

At 60° C., a ratio of the storage modulus of the adhesive layer to the storage modulus of the intermediate support layer is 1:1.1 to 1:1.3.

[Equation 6]

At 60° C., a ratio of the storage modulus of the buffer layer to the storage modulus of the intermediate support layer is 1:1.1 to 1:1.3.

During the back grinding process of the wafer, heat is generated, and when the storage modulus at high temperatures is too low, the sticky residue is caused by an increase in fluidity of each layer, and thus a residue is left or the thickness of the film is changed, thereby causing a thickness deviation in the final chip.

The adhesive film for wafer back grinding can exhibit a storage modulus in the above range at 60° C. and exhibit the desired effect even during the wafer back grinding process.

The adhesive film for wafer back grinding may include the buffer layer, the intermediate support layer, and the adhesive layer, and the total storage modulus of the buffer layer, the intermediate support layer, and the adhesive layer may range from about 0.01 MPa to about 0.3 MPa at 25° C. and range from about 0.01 MPa to about 0.1 MPa at 60° C.

### EXAMPLES

Hereinafter, the configuration and operation of the present disclosure will be described in more detail through exemplary embodiments of the present disclosure. However, these examples are suggested as preferred examples of the present disclosure and may not be construed as limiting the present disclosure thereby in any sense.

### Preparing Example 1 (C1): Preparing of Composition for Forming Buffer Layer

A mixture of mixing monomers of 63 parts by weight of 2-ethylhexyl acrylate (2-EHA), 30 parts by weight of isobornyl acrylate (IBOA), and 7 parts by weight of methyl acrylate (MA) was added to a reactor provided with a cooling device for refluxing nitrogen gas and facilitating temperature control. In addition, 0.4 weight part of azobisisobutyronitrile (AIBN) that is a reaction initiator, was added and polymerized at 60° C. for 6 hours under a nitrogen atmosphere to obtain an acryl-based photocurable polymer having a weight average molecular weight of 700,000 g/mol.

A composition for a buffer layer having a storage modulus of Table 2 was prepared by adding 0.7 weight part of Irgacure 651 as a photoinitiator and 0.2 weight part of 1,6-hexanediol diacrylate (HDDA) as a curing agent to the acryl-based photocurable polymer.

### Preparing Example 2-1 (B1): Preparing of Composition for Forming Intermediate Support Layer

A mixture of mixing monomers of 60 parts by weight of n-butylacrylate (BA), 10 parts by weight of 2-ethylhexylacrylate (2-EHA), 15 parts by weight of methylacrylate (MA), 10 parts by weight of 2-hydroxyethylacrylate (2-HEA), and 5 parts by weight of acrylic acid (AA) was added to a reactor provided with a cooling device for refluxing nitrogen gas and facilitating temperature control. Then, 100 parts by weight of ethyl acetate (EAc) as a solvent was added to 100 parts by weight of the monomer mixture. In addition, a concentration of 0.1 parts by weight of azobisisobutyronitrile, a reaction initiator, was added under a nitrogen atmosphere and polymerized at 60° C. for 6 hours to obtain an acryl-based adhesive resin having a weight average molecular weight of 800,000 g/mol.

A composition for an intermediate support layer for forming the intermediate support layer having the storage modulus of Table 2 was prepared by adding an 1 part by weight of an isocyanate crosslinking agent (manufactured by Nippon Polyurethane Kogyo Co., Ltd., trade name Coronate CJ) to the acryl-based adhesive resin and then sufficiently mixing the same.

### Preparing Example 2-2 (B2): Preparing of Composition for Forming Intermediate Support Layer

In Preparing Example 2-1 (B1), 55 parts by weight of n-butylacrylate (BA), 25 parts by weight of 2-ethylhexylacrylate (2-EHA), 5 parts by weight of methylacrylate (MA), 10 parts by weight of 2-hydroxyethyl acrylate (2-HEA), 5 parts by weight of acrylic acid (AA), 0.2 parts by weight of isobisbutyronitrile, and 100 parts by weight of ethyl acetate (EAc) were mixed in different contents. In addition, the mixture thus obtained was polymerized at 60° C. for 6 hours under a nitrogen atmosphere to obtain an acryl-based adhesive resin having a weight average molecular weight of 500,000 g/mol. Other than the above, a composition for an intermediate support layer for forming an intermediate support layer having the storage modulus of Table 2 was prepared in the same method as in Preparing Example 2-1 (B1).

### Preparing Example 3-1 (A1): Preparing of Composition for Forming Adhesive Layer

A mixture of mixing monomers of 60 parts by weight of 2-ethylhexyl acrylate (2-EHA), 30 parts by weight of 2-ethylhexyl methacrylate (2-EHMA), and 10 parts by weight of 2-hydroxyethyl acrylate (2-HEA) was added to a reactor provided with a cooling device for refluxing nitrogen gas and facilitating temperature control.

Subsequently, 100 parts by weight of ethyl acetate (EAc) as a solvent was added to 100 parts by weight of the monomer mixture and sufficiently mixed at 30° C. for 30 minutes or more while injecting nitrogen to remove oxygen in the reactor. Thereafter, a temperature was raised and maintained at 50° C., 0.6 parts by weight of azobisisobutyronitrile (AIBN) that is a reaction initiator was added and polymerized for 24 hours after a reaction was initiated, thereby preparing a first reactant.

1 part by weight of 2-methacryloyloxyethyl isocyanate (MOI) and 0.2 parts by weight of a catalyst (dibutyl tin dilaurate (DBTDL)) with respect to an MOI were mixed with the primary reactant, and the mixture was reacted at 40° C. for 24 hours to obtain an acryl-based adhesive resin having a weight average molecular weight of 500,000 g/mol.

0.5 parts by weight of Irgacure 184 (BASF) as a photopolymerization initiator and 1 part by weight of an isocyanate crosslinking agent (Nippon Polyurethane Kogyo Co., trade name: Coronate C) as a crosslinking agent were added to 100 parts by weight of the acryl-based adhesive resin and then sufficiently mixed to prepare a composition for an adhesive layer for forming the adhesive layer having the storage modulus of Table 2.

### Preparing Example 3-2 (A2): Preparing of Composition for Forming Adhesive Layer

In Preparing Example 3-1 (A1), instead of the monomer mixture of Preparing Example 3-1 (A1), a mixture of monomers consisting of 71 parts by weight of n-butylacrylate (BA), 19 parts by weight of methyl acrylate (MA), and 10 parts by weight of hydroxyethyl acrylate (HEA) was added and reacted to obtain an acryl-based adhesive resin having a weight average molecular weight of 500,000 g/mol. Other than the above, a composition for an adhesive layer for forming an adhesive layer having the storage modulus of Table 2 was prepared in the same method as in Preparing Example 3-1 (A1).

### Example 1

The composition for a buffer layer of Preparing Example 1 (C1) was coated on PET (a thickness of 50 μm) so that the buffer layer had a thickness of 70 μm. In addition, 1 J/cm² of UV was radiated (UV radiation equipment: UV Scan Conveyor; LKUV system Co., Ltd.) to form a cured buffer layer.

The composition for an intermediate support layer of Preparing Example 2-1 (B1) was coated on a release-treated PET (a thickness of 50 μm) to a thickness of 20 μm. After coating, drying was performed at 100° C. for 3 minutes. In addition, the buffer layer and the intermediate support layer were bonded to manufacture a first composite film having the buffer layer and the intermediate support layer.

Subsequently, the composition for an adhesive layer of Preparing Example 3-2 (A2) was coated on a biaxially stretched PET film having a thickness of 25 μm to a thickness of 10 μm, and after coating, drying was performed at 100° C. for 3 minutes. Accordingly, a second composite film having an adhesive layer was manufactured.

An adhesive film for wafer back grinding having a total thickness of 100 μm (the thicknesses of the substrate layer and the release layer were removed from the total thickness) (buffer layer of 70 μm+intermediate support layer of 20 μm+adhesive layer of 10 μm) by removing the release-treated PET of the first composite film and bonding the second composite film.

### Example 2-3 and Comparative Examples 1 to 5

In the adhesive film for wafer back grinding of Example 1, the type and thickness of each layer constituting the adhesive film for wafer back grinding were changed as shown in Table 1, and each adhesive film for wafer back grinding was manufactured.

TABLE 1

| Items | | Exam- | Exam- | Exam- | Comparative | Comparative | Comparative | Comparative | Comparative |
|---|---|---|---|---|---|---|---|---|---|
| (thickness) | | ple 1 | ple 2 | ple 3 | Example 1 | Example 2 | Example 3 | Example 4 | Example 5 |
| Adhesive | A1 | | 10 | | 10 | 10 | | 5 | |
| layer (A) | A2 | 10 | | 30 | | | 10 | | 5 |
| Intermediate | B1 | 20 | 20 | 40 | | | | 5 | 5 |
| support | B2 | | | | | 20 | 20 | | |
| layer (B) | | | | | | | | | |
| Buffer | C1 | 70 | 70 | 500 | 90 | 70 | 70 | 90 | 90 |
| layer (C) | | | | | | | | | |

| | | | | | | | | |
|---|---|---|---|---|---|---|---|---|
| Thickness | 20 | 20 | 7 | — | 20 | 20 | 5 | 5 |
| ratio (%) of | | | | | | | | |
| intermediate | | | | | | | | |
| support layer | | | | | | | | |

### Evaluation

### Experimental Example 1: Storage Modulus (MPa)

Each shear storage modulus was measured using a Rheometer (TA instruments Co., Ltd., ARES-G2) that is a shear storage modulus measuring device. Specifically, samples of a size of 8 mm in diameter×1 mm in thickness were prepared by laminating each single layer formed of the composition of each layer constituting the adhesive film for wafer back grinding of the Examples 1 to 3 and Comparative Examples 1 to 5. In addition, for each sample, the shear storage modulus was measured under an environment of −20° C. to 120° C. at 1 Hz, and the shear storage modulus at 25° C. and 60° C. was recorded, which is shown in Table 2 below.

In addition, ratios of the storage modulus of the adhesive layer and the storage modulus of the intermediate support layer (Expressions 3 and 5) and the storage modulus of the buffer layer and the storage modulus of the intermediate support layer (Expressions 4 and 6) were calculated, which is shown in Table 2.

### Experimental Example 2: Embeddability

The adhesive films for wafer back grinding of the examples and the comparative examples was laminated on a semiconductor circuit surface (=a surface of a wafer) on which a bump (a diameter of 65 μm and a height of 70 μm) was formed using mount equipment (CUON Solution Co., Ltd.; CUWLS-12) under conditions of a mount pressure of 500 KPa, a roller temperature of 50° C., and a speed of 5 mm/s.

Thereafter, embeddability was calculated by measuring a diameter Df of the adhesive film for wafer back grinding, which covers the bump using an optical microscope (Nikon Co., Ltd.; MM-40) at 20× magnification and dividing the diameter by a diameter of the bump Di (65 μm) as represented by Expression 7. The closer the embeddability is to 1, the higher the embeddability for the bump.

$$Embeddability = Df / Di \qquad [ Expression 7 ]$$

### Experimental Example 3: Presence or Absence of Residue

After attaching the adhesive films for wafer back grinding of the examples and the comparative examples to the semiconductor circuit surface (=a surface of a wafer), back grinding was performed on the wafer having a thickness of 725 μm to a thickness of 170 μm using back grinding equipment (DISCO Co., Ltd.; DGP8760).

After the back grinding process was completed, UV A 300 mJ/cm² was radiated using exposure equipment (SEIMYUNG VACTRON Co., Ltd.; TRSJ-3000). Then, after a heat sealing tape (MBS-100R) was thermally bonded to one outer side of the adhesive film for wafer back grinding at 230° C., the adhesive film for wafer back grinding was removed.

After the back grinding process, the presence or absence of a residue of an adhesive was confirmed through microscopic observation at 20 points of the surface of the wafer with the adhesive film removed. A specific method is as follows.

The size of the residue at 20 points in the back-ground wafer was measured, and when there was no residue, it was evaluated as “good (NO),” and when a residue of 10 μm or larger occurred, it was evaluated as “bad (YES).”

TABLE 2

| | | | Exam- | Exam- | Exam- | Comparative | Comparative | Comparative | Comparative | Comparative |
|---|---|---|---|---|---|---|---|---|---|---|
| Items | | | ple 1 | ple 2 | ple 3 | Example 1 | Example 2 | Example 3 | Example 4 | Example 5 |
| Storage | Adhesive layer (A) | 25° C. | 0.079 | 0.119 | 0.079 | 0.119 | 0.119 | 0.079 | 0.119 | 0.079 |
| modulus | | 60° C. | 0.081 | 0.072 | 0.081 | 0.072 | 0.072 | 0.081 | 0.072 | 0.081 |
| | Intermediate | 25° C. | 0.162 | 0.162 | 0.162 | — | 0.054 | 0.054 | 0.162 | 0.162 |
| | support layer (B) | 60° C. | 0.114 | 0.114 | 0.114 | — | 0.023 | 0.023 | 0.114 | 0.114 |
| | Buffer layer (C) | 25° C. | 0.088 | 0.088 | 0.088 | 0.088 | 0.088 | 0.088 | 0.088 | 0.088 |
| | | 60° C. | 0.063 | 0.063 | 0.063 | 0.063 | 0.063 | 0.063 | 0.063 | 0.063 |
| | Adhesive | 25° C. | 1:2.05 | 1:1.36 | 1:2.05 | — | 1:0.45 | 1:0.68 | 1:1.36 | 1:2.05 |
| | layer:intermediate | 60° C. | 1:1.41 | 1:1.58 | 1:1.41 | — | 1:0.32 | 1:0.28 | 1:1.58 | 1:1.41 |
| | support layer | | | | | | | | | |
| | Buffer | 25° C. | 1:1.84 | 1:1.84 | 1:1.84 | — | 1:0.61 | 1:0.61 | 1:1.84 | 1:1.84 |
| | layer:intermediate | 60° C. | 1:1.81 | 1:1.81 | 1:1.81 | — | 1:0.37 | 1:0.37 | 1:1.81 | 1:1.81 |
| | support layer | | | | | | | | | |

| | | | | | | | | |
|---|---|---|---|---|---|---|---|---|
| Embeddability | 1.58 | 1.67 | 1.31 | 1.82 | 1.42 | 1.33 | 2.06 | 1.98 |
| Presence or absence of residue | NO | NO | NO | YES | YES | YES | YES | YES |

As shown in Table 1, the adhesive films for wafer back grinding of the examples have a thickness ratio of the intermediate support layer exceeding 5% based on the total thickness of the buffer layer, the intermediate support layer, and the adhesive layer, and as shown in Table 2, the adhesive layer, the intermediate support layer, and the buffer layer satisfy Expressions 1 and 2 and it can be confirmed that the embeddability for the bump is excellent and no residue occurs after the process.

On the other hand, in Comparative Example 1 that does not include the intermediate support layer, Comparative Examples 2 and 3 that do not satisfy Expressions 1 and 2, and Comparative Examples 4 and 5 in which the thickness ratio of the intermediate support layer is outside the scope of the present disclosure, it can be confirmed that embeddability is insufficient or the support strength between the adhesive layer and the buffer layer is weak, thereby causing a residue.

The adhesive film for wafer back grinding according to the present disclosure can increase the support strength between the intermediate support layer and the buffer layer and between the intermediate support layer and the adhesive layer and at the same time, maximizing bump fillability (embeddability) by including the intermediate support layer, thereby preventing the occurrence of cracks in the wafer, damage to a chip, and the like during back grinding. In addition, it is possible to reduce or suppress the generation of the residue of the adhesive layer when peeling the adhesive film for wafer back grinding from the wafer. Accordingly, it is possible to improve wafer treatment processability and the quality of the manufactured semiconductor chip.

Effects of the present specification are not limited to the above-described effects, and other effects that are not mentioned will be able to be clearly understood by those skilled in the art from the following description. Specific effects together with the above-described effects are described together with a description of the following detailed matters for carrying out the disclosure.

Although the present disclosure has been described above, the present disclosure is not limited by the embodiments disclosed herein, and it is apparent that various modifications can be made by those skilled in the art within the scope of the technical spirit of the present disclosure. In addition, even when the operational effects according to the configuration of the present disclosure have not been explicitly described in the description of the embodiments of the present disclosure, it goes without saying that the effects predictable by the corresponding configuration should also be recognized.

### DESCRIPTION OF REFERENCE NUMERALS

100: adhesive film for wafer back grinding
200: wafer before back grinding process
210: wafer after back grinding process
300: bump
R: region in which residue of adhesive is left
10: adhesive layer
20: intermediate support layer
30: buffer layer
40: substrate layer
50: release film

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. An adhesive film for wafer back grinding, comprising:
a substrate layer,
a buffer layer disposed on the substrate layer,
an intermediate support layer disposed on the buffer layer; and
an adhesive layer disposed on the intermediate support layer,
wherein a thickness of the intermediate support layer exceeds 5% based on a total thickness of the buffer layer, the intermediate support layer, and the adhesive layer;
wherein at 25° C., a storage modulus of the adhesive layer is less than a storage modulus of the intermediate support layer, and
wherein at 25° C., a storage modulus of the buffer layer is less than a storage modulus of the intermediate support layer.

2. The adhesive film of claim 1, wherein the intermediate support layer is a thermosetting product of a composition including a thermoplastic acryl-based resin.

3. The adhesive film of claim 1, wherein a storage modulus of the intermediate support layer at 25° C. ranges from about 0.03 MPa to about 0.3 MPa.

4. The adhesive film of claim 1, wherein a storage modulus of the adhesive layer at 25° C. ranges from about 0.02 MPa to about 0.2 MPa.

5. The adhesive film of claim 1, wherein a storage modulus of the buffer layer at 25° C. ranges from about 0.02 MPa to about 0.2 MPa.

6. The adhesive film of claim 1,
wherein at 25° C., a ratio of a storage modulus of the adhesive layer to a storage modulus of the intermediate support layer ranges from about 1:1.1 to about 1:1.4; and
wherein at 25° C., a ratio of a storage modulus of the buffer layer to a storage modulus of the intermediate support layer ranges from about 1:1.1 to about 1:1.4.

7. The adhesive film of claim 1,
wherein at 60° C., a ratio of a storage modulus of the adhesive layer to a storage modulus of the intermediate support layer ranges from about 1:1.1 to about 1:1.3; and
wherein at 60° C., a ratio of a storage modulus of the buffer layer to a storage modulus of the intermediate support layer ranges from about 1:1.1 to about 1:1.3.

8. The adhesive film of claim 1, wherein a total thickness of the buffer layer, the intermediate support layer and the adhesive layer ranges from about 20 μm to about 600 μm.

9. The adhesive film of claim 1, wherein a thickness of the intermediate support layer ranges from about 1 μm to about 40 μm.

10. The adhesive film of claim 1, wherein the adhesive film is applied to protect a front side of a semiconductor wafer upon which circuitry of an electronic device has been formed while a back side grinding process of a wafer on which a bump is formed is carried out.

11. A method for protecting electronic device components formed on a front side of a semiconductor wafer during back side grinding of the wafer, the method comprising:
applying an adhesive film to the front side of the wafer;
grinding a back side of the wafer; and
removing the film from the front side of the wafer,
wherein the adhesive film comprises:
a substrate layer,
a buffer layer disposed on the substrate layer,
an intermediate support layer disposed on the buffer layer; and
an adhesive layer disposed on the intermediate support layer,
wherein a thickness of the intermediate support layer exceeds 5% based on a total thickness of the buffer layer, the intermediate support layer, and the adhesive layer,
wherein at 25° C., a storage modulus of the adhesive layer is less than a storage modulus of the intermediate support layer, and
wherein at 25° C., a storage modulus of the buffer layer is less than a storage modulus of the intermediate support layer.

12. The method of claim 11, wherein the front side of the wafer comprises a bump.

13. The method of claim 12, wherein the applying step leaves no gas pockets between the intermediate support layer and the front side of the wafer.

14. The method of claim 11, wherein the removing step leaves no substantial amount of adhesive or adhesive byproduct behind on the front side of the wafer.
